(19) United States
(12) Patent Application Publication
(10) Pub. No.: US 2026/0096402 A1
(43) Pub. Date: Apr. 2, 2026

(54) SILICON OXYNITRIDE FILM TO PROTECT SILICON NITRIDE

(71) Applicant: TEXAS INSTRUMENTS INCORPORATED, Dallas, TX (US)

(72) Inventor: Jackson Bauer, Rowlett, TX (US)

(21) Appl. No.: 18/901,490

(22) Filed: Sep. 30, 2024

(51) Int. Cl. H01L 21/762; H01L 29/06; H01L 29/40; H01L 29/66; H01L 29/78

(52) U.S. Cl. CPC H10W 10/012; H10D 30/0281; H10D 30/65; H10D 62/116; H10D 64/111; H10W 10/13

(57) ABSTRACT

Described examples include an integrated circuit that includes a trench extending into a semiconductor substrate. A silicon nitride body is located within the trench. A polysilicon electrode extends over the silicon nitride body, and a silicon oxynitride layer is located between the silicon nitride body and the polysilicon electrode.

### TECHNICAL FIELD

This relates generally to integrated circuit fabrication, and in particular examples to protection of silicon nitride layers.

### BACKGROUND

Laterally diffused metal-oxide semiconductor (LDMOS) transistors are an example of a field-effect transistor formed in integrated circuits. LDMOS transistors are structured for higher voltage applications by extending the drain of the transistor away from the channel region of the transistor. In addition, structures may be added in the drain region to minimize local electric fields. An example structure is a local oxidation of silicon (LOCOS) layer grown between the channel and the drain diffusion. A doped region may also be included at the bottom of the LOCOS layer. These structures help smooth the field lines through the extended drain and thus help avoid high localized fields.

One problem with using a LOCOS layer in LDMOS transistors is the nature of the oxidation process that forms the LOCOS layer. About half of the layer is above the surface of the substrate. This creates surface topography that may either make subsequent photolithography steps more difficult due to depth of focus issues or requires a planarization step such as chemical-mechanical polishing (CMP). In addition, while the contour of the lower surface of the LOCOS layer has some advantageous features, such as lacking sharp corners, the typical “bird's beaks” that forms at the ends of the LOCOS layer may increase device size. Also, silicon dioxide has a relatively low-dielectric permittivity. Dielectric permittivity is often expressed as a dimensionless value “k” that is relative to the real part of the complex permittivity of a material and is sometimes referred to as “relative permittivity” or “dielectric constant”. A capacitor made with a higher-k dielectric will have a greater capacitance than a capacitor made with a lower-k dielectric, all other parameters being equal. This is important because some LDMOS transistor designs have an electrode (sometimes an extension of the gate electrode) over the LOCOS layer to serve as a field plate to further manage the fields in the drain region under the LOCOS layer. However, the lower-k nature of silicon dioxide limits the effectiveness of this field plate.

### SUMMARY

One general aspect includes an integrated circuit that includes a trench extending into a semiconductor substrate. A silicon nitride body is located within the trench. A polysilicon electrode extends over the silicon nitride body, and a silicon oxynitride layer is located between the silicon nitride body and the polysilicon electrode.

Another general aspect includes an electronic device. The integrated circuit includes an epitaxial layer over a semiconductor substrate. A transistor formed in or over the epitaxial layer includes a source and a drain formed in the epitaxial layer, a cavity in a surface of the epitaxial layer between the source and the drain, a silicon nitride body in the cavity, a gate electrode extending from the source toward the drain, a gate dielectric between the gate electrode and the semiconductor substrate that extends from the source toward the drain, and a silicon oxynitride layer between the gate electrode and the silicon nitride body.

Another general aspect includes a method of forming an integrated circuit. The method includes forming a silicon nitride body over a semiconductor substrate. The silicon nitride body is heated in the presence of oxygen, thereby forming a silicon oxynitride layer located on the silicon nitride body and having a thickness of at least 2 nm.

### BRIEF DESCRIPTION OF THE DRAWINGS

FIG. 1 is a side view diagram of an example LDMOS transistor.

FIGS. 2A-M (collectively “FIG. 2”) are side view diagrams illustrating the fabrication of an LDMOS transistor such as the LDMOS transistor of FIG. 1.

FIG. 3 is a flow diagram of a process, e.g. for forming an electronic device such as the LDMOS transistor of FIG. 1.

### DETAILED DESCRIPTION

In the drawings, corresponding numerals and symbols generally refer to corresponding parts unless otherwise indicated. The drawings are not necessarily drawn to scale.

In this description, the term “coupled” may include connections made with intervening elements, and additional elements and various connections may exist between any elements that are “coupled.” In addition, an element that is “on” another element may include a third element between the element and another element that the element is “on.”

Various examples of the present disclosure describe the conversion of a portion of a silicon nitride feature to silicon oxynitride (SiON), and electronic devices made using this scheme. The silicon oxynitride has a lower etch rate in some silicon nitride (SiN) removal processes. Thus, the silicon oxynitride may protect the silicon nitride feature during removal of later-formed silicon nitride layers such as hard masks used in some patterning processes. In one specific and non-limiting example, the surface of a silicon nitride isolation feature in a shallow trench, used as a field relief dielectric, is converted to SiON. The SiN within the trench is protected from removal by hot phosphoric acid strips used to remove layer-formed SiN layers employed during formation of the electronic device. While such examples may be expected to provide various improvements, for example more uniform performance of transistors that include the SiN field relief feature, no particular result is a requirement of the present disclosure unless explicitly recited in a particular claim.

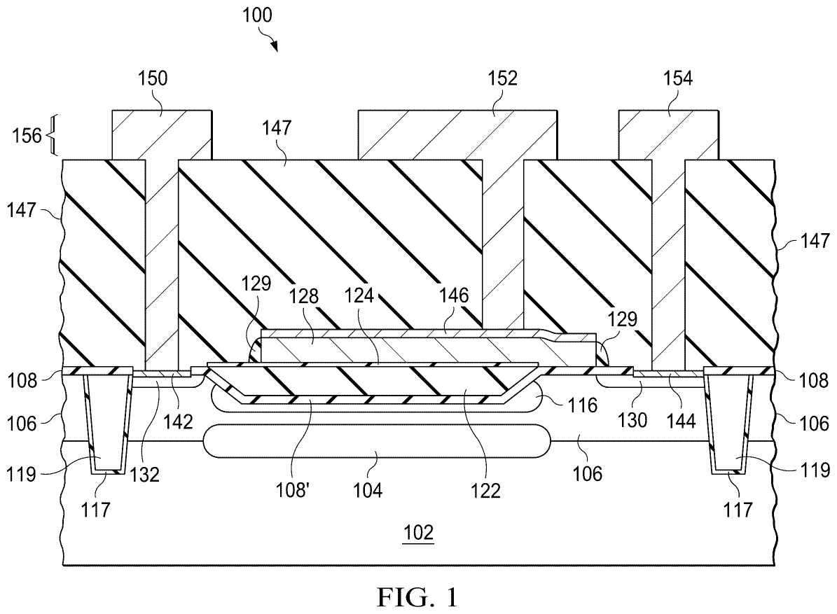

FIG. 1 is a side view diagram of an LDMOS transistor 100. Substrate 102 is a semiconductor substrate, e.g. crystalline silicon, and may be an epitaxial layer formed over a bulk wafer or “handle”. Buried layer 104 is formed between substrate 102 and an epitaxial layer 106 doped a first conductivity type, e.g. p-type. Although substrate 102 is termed the “substrate,” epitaxial layer 106 (or “epi layer”) serves as the “substrate” on, over and in which the transistor 100 is formed. A thermal oxide layer 108 covers portions of the top surface of the epi layer 106. Shallow trench isolation regions that include silicon dioxide layer 117 and polycrystalline silicon fill 119 (“polysilicon”) help prevent interactions with other elements formed in substrate 102. Drain 132 has a second conductivity type, e.g. n-type, and is coupled to lead 150 through silicide layer 142. Source 130 also has the second conductivity type and is coupled to lead 154 through silicide layer 144. A field relief structure includes silicon nitride layer 122 in a cavity, or trench, in epitaxial layer 106. The thermal oxide layer extends into the cavity and provides an oxide liner 108′. The cavity extends into doped region 116 that has the second conductivity type. A segment of silicon dioxide layer 108 extends to serve as a gate dielectric layer between gate electrode 128 and a channel region of the epi layer 106. Although silicon dioxide layer 108 is shown as a continuous layer, in some implementations some portions of silicon dioxide layer 108 result from an earlier thermal oxide layer on some portions of the epi layer 106 and regrowth of silicon dioxide layer on those portions, e.g. to provide a high-quality gate oxide layer. A portion of the gate electrode 128 that is located over the silicon nitride layer 122 may act as a field plate electrode and may be referred to as such. Silicon oxynitride layer 124 is located on the upper surface of silicon nitride layer 122 between the field plate electrode and the silicon nitride layer 122 and may protect silicon nitride layer 122 from subsequent etching steps as summarized above and addressed in greater detail hereinbelow. Silicide layer 146 on gate electrode 128 serves as a contact for lead 152. Sidewall spacers 129 may space dopant implants away from the gate electrode 128, e.g. when doping the source region 130, and may also prevent the formation of silicide that could short to the gate electrode 128. Lead 150, lead 152 and lead 154 extend through vias in first level metal oxide 147 and extend horizontally and into the page to provide interconnections in first level metal 156. Additional interlevel oxide layers and metal layers may be used to provide more complex interconnections in the integrated circuit.

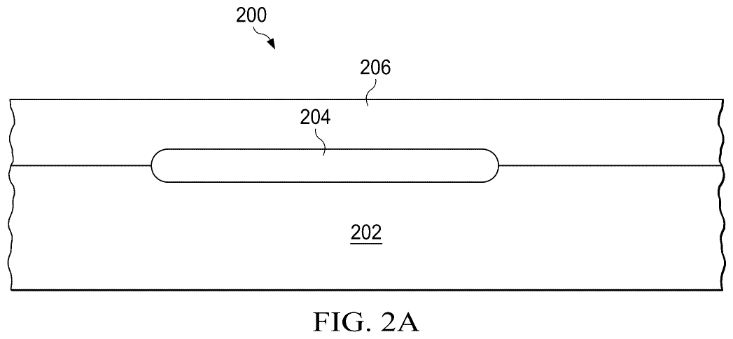

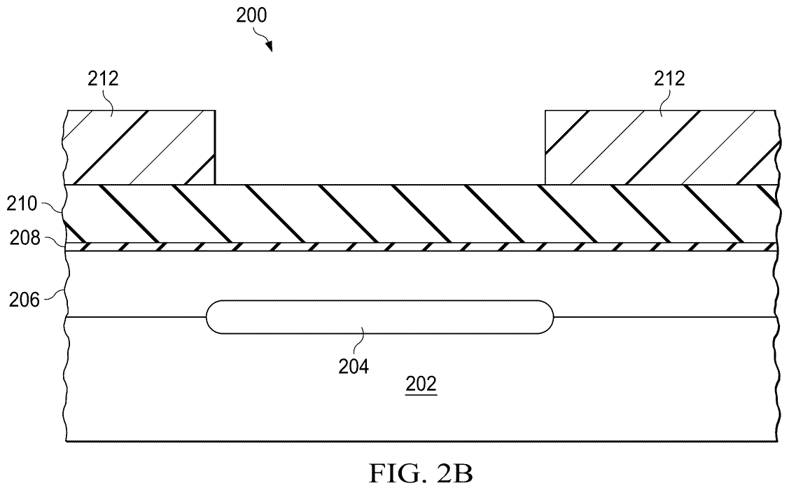

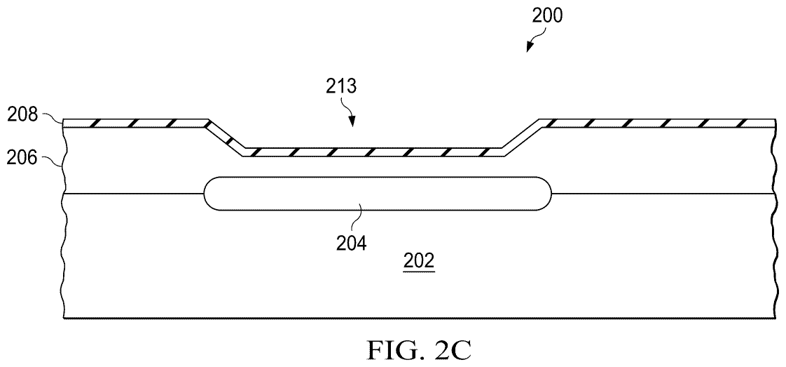

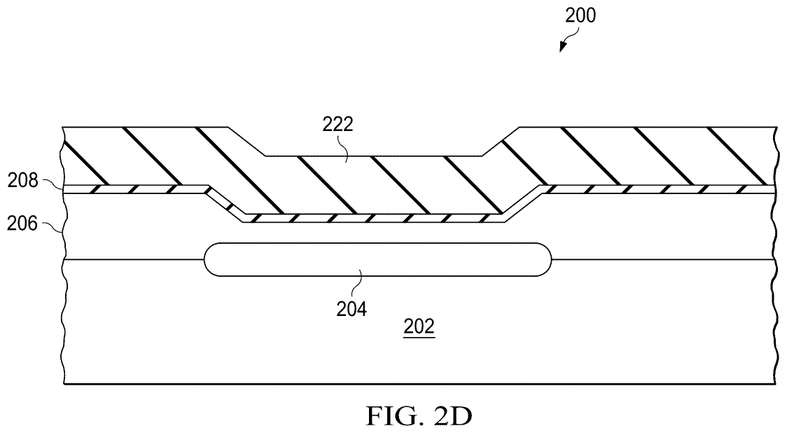

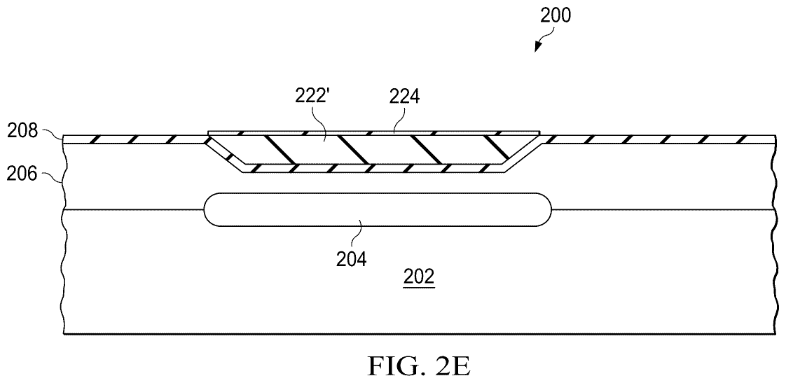

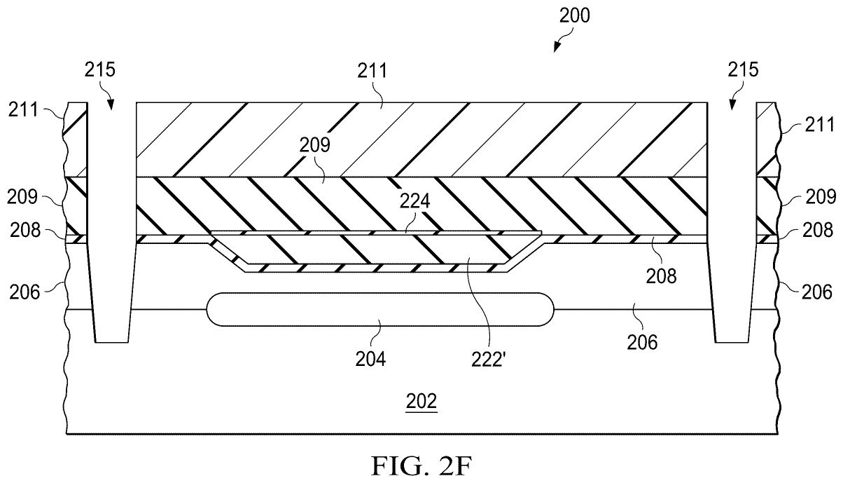

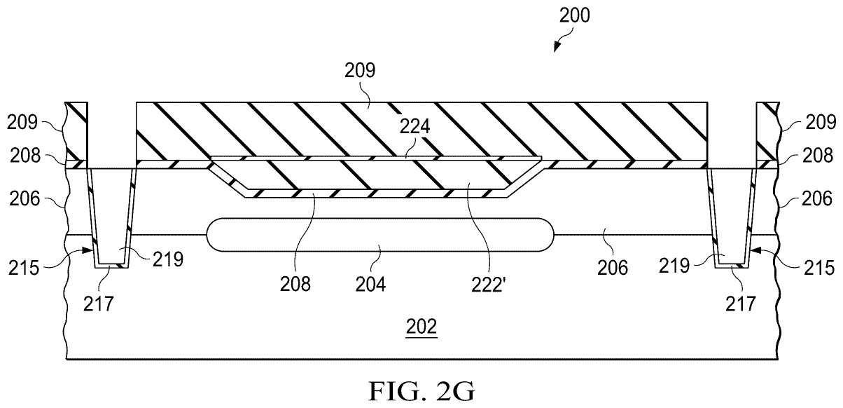

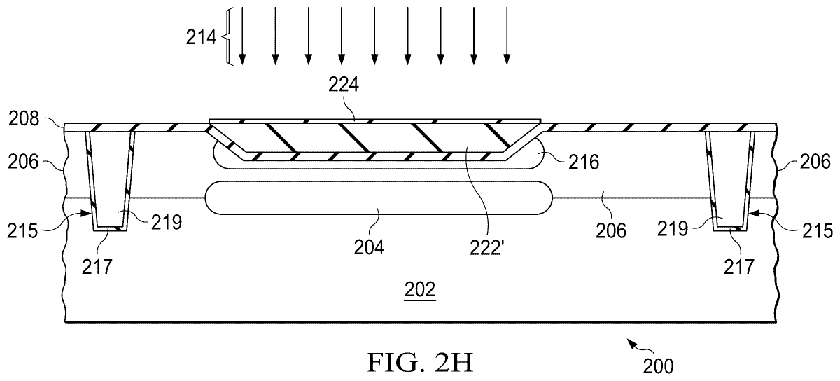

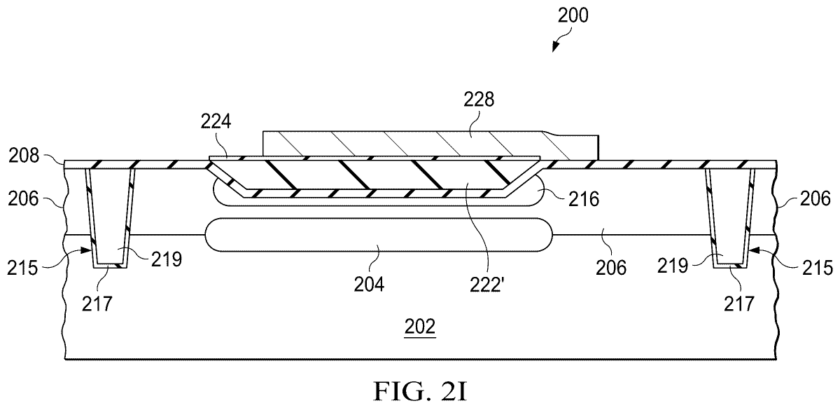

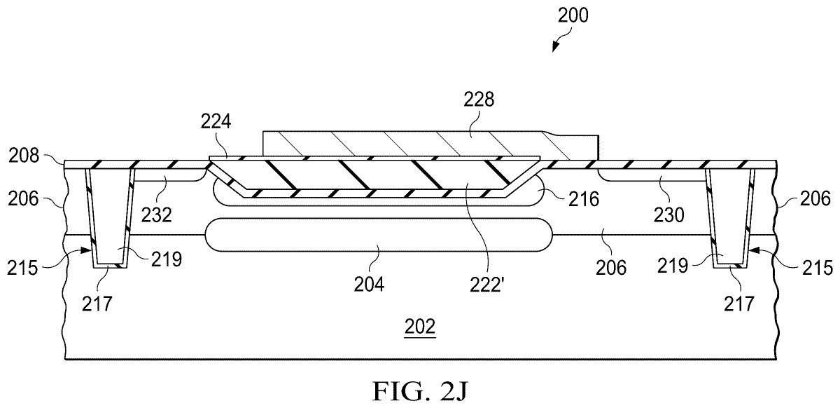

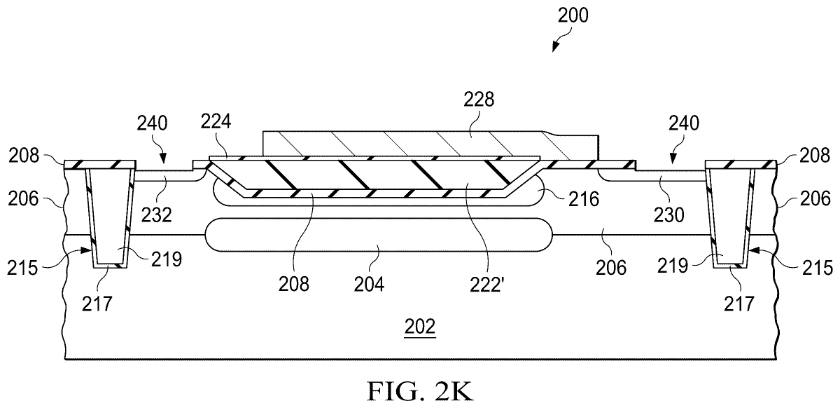

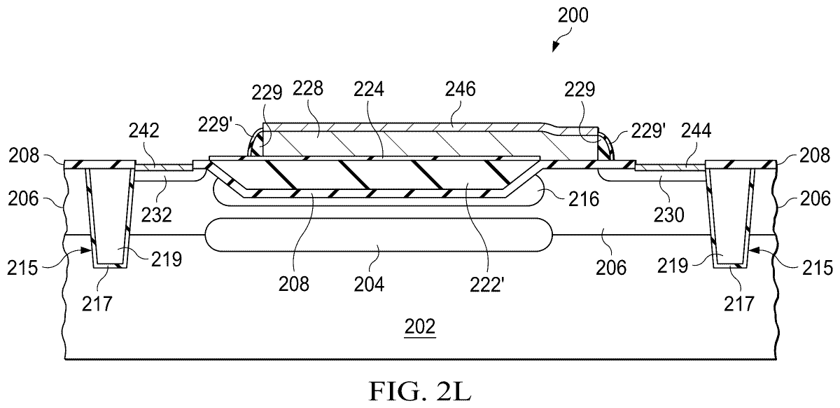

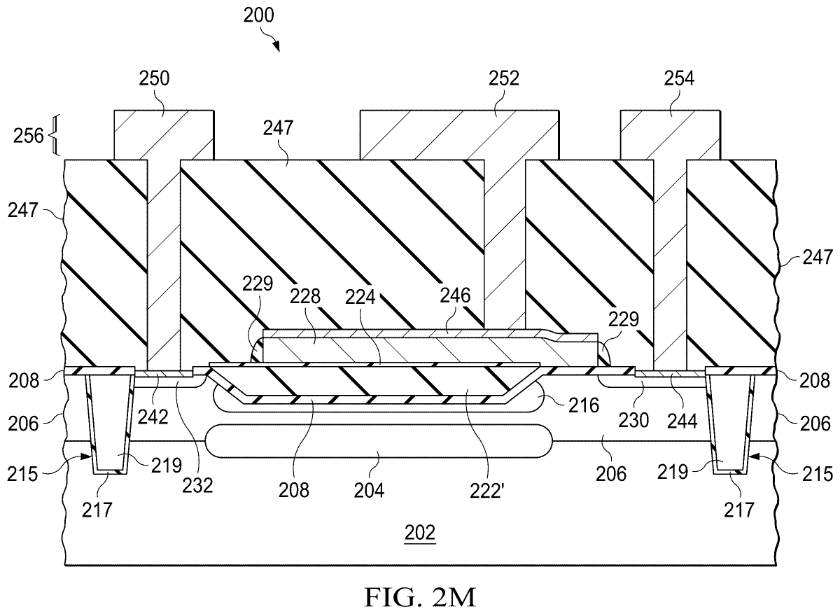

FIGS. 2A-M (collectively “FIG. 2”) are side view diagrams illustrating the fabrication of LDMOS transistor 200 which may be an example of LDMOS transistor 100. Referring initially to FIG. 2A, the transistor 200 is shown after formation of a buried layer 204 between a substrate 202 and an epi layer 206. The substrate 202 may be as described for the substrate 102, e.g. an epitaxial layer having a first conductivity type, such as p-type, over a handle wafer. The buried layer 204 may be formed by a patterned implantation of dopant ions having a conductivity opposite to that of substrate 202, followed by growth of epi layer 206. The epi layer 206 may be in-situ doped to have the first conductivity type. As illustrated in FIG. 2A, buried layer 204 extends into epitaxial layer 206 during the epitaxial deposition process. An optional diffusion anneal may also be used to form the buried layer 204. Collectively, the combination of epitaxial layer 206 and substrate 202 may be referred to as a “substrate.”

FIG. 2B shows the LDMOS transistor 200 at a later stage of formation. Silicon dioxide layer 208 is formed by thermal oxidation of epitaxial layer 206. Silicon dioxide layer 208 may have a thickness of approximately 20 nm. Silicon nitride layer 210 is formed on silicon dioxide layer 208 by chemical vapor deposition (CVD) and may have a thickness of 100 nm to 250 nm. In this context, silicon nitride layer 210 serves as a hard mask. The term “hard mask” refers to a layer that is patterned and used for etching portions below the hard mask and may have a significantly lower etch rate than the portions being etched for a given etchant. For example, silicon nitride has a significantly lower etch rate in wet etching using hydrofluoric acid (HF) than silicon dioxide. For this and other reasons, silicon nitride is used as a hard mask in many fabrication steps. Photoresist layer 212 is formed and patterned on silicon nitride layer 210 using photolithography. Silicon nitride layer 210 is then etched by a suitable etch process, e.g. using difluoromethane (CH₂F₂), helium (He), methane (CH₄), and nitrogen (N₂) with photoresist layer 212 serving as a mask.

FIG. 2C shows a cavity 213 in epitaxial layer 206 formed in part using the silicon nitride layer 210 hard mask. Cavity 213 (or trench 213) is etched using the patterned silicon nitride layer 210 (FIG. 2B) as a mask. Using techniques such as crystallographic oriented etching, sidewall spacers on silicon nitride layer 210, and careful selection of etch chemistries, the shape of cavity 213 can provide a favorable shape for mitigating local fields in the extended drain, the effect of which may exceed that of a LOCOS layer. As can be seen in FIG. 2C, silicon nitride layer 210 has been removed after formation of cavity 213, e.g. using a hot phosphoric acid (H₃PO₄) bath. Such an acid bath may have a temperature near the boiling point corresponding to the acid concentration, for example about 160° C.-180° C. Many process flows include the use of different silicon nitride hard masks at several stages of manufacturing. Removal of the various hard masks can damage silicon nitride features that are not to be removed, such as by thinning or otherwise altering the geometry of such features. This aspect is more fully explained hereinbelow.

Silicon dioxide layer 208 is grown on the surface of the epi layer 206, including within the cavity 213. The silicon dioxide layer 208 may be carried forward from FIG. 2B, with portions removed and regrown at various stages of manufacturing to remove processing damage to epitaxial layer 206 and to provide a silicon dioxide layer of specific thicknesses and qualities before forming a gate electrode layer. For simplicity the illustrated silicon dioxide layer 208 is represented without limitation as persistent.

In FIG. 2D, silicon nitride field layer 222 has been formed on silicon dioxide layer 208, e.g. using CVD to a thickness that completely fills cavity 213, plus an additional thickness 0.5 to 1 times the depth of the cavity 213. In some non-limiting examples, the thickness of the silicon nitride field layer 222 as deposited is in a range from about 150 nm to about 250 nm, corresponding to depth of the cavity 213 of about 300 nm.

FIG. 2E shows the transistor 200 after removal of silicon nitride field layer 222 in field areas, with a remaining portion 222′ in cavity 213. The remaining portion is referred to hereinafter as the field-relief nitride 222′. The silicon nitride field relief layer 222 may be removed by CMP, for example.

The structure that results after removal of the field portions of the field-relief nitride 222′ includes a silicon nitride surface. The partially formed transistor 200 is then heated in the presence of an oxygen ambient to convert some of the silicon nitride at the surface of the field-relief nitride 222′ to a silicon oxynitride layer 224. Silicon oxynitride may be represented by the empirical formula SiON, but it is noted that the proportion silicon, oxygen and nitrogen in the SiON layer 224 is not limited to any particular value and may differ from an ideal stoichiometry. In a nonlimiting example, the field-relief nitride 222′ is heated in a tube furnace at an oxidation temperature in a range of from about 900° C. to about 1,100° C. for greater than 20 minutes. Including other process steps such as ramp up from a loading temperature and ramp down to an unloading temperature, the transistor 200, and a handle wafer on which it is formed, may be at an elevated temperature for three to four hours. In addition, the oxidation process may include an anneal after oxygen exposure. The precise process parameters are expected to be dependent on the equipment used, gas quality, and other factors. A specific example is summarized in the following chart, in which “slm” is standard liters per minute:

| | | | | | Temp Change | | | |
|---|---|---|---|---|---|---|---|---|
| | | | | | Rate | | | |
| Step | Start temp | | End temp | | (deg C./min) | Time (min) | O₂ (slm) | N₂ (slm) |
| Load | 700° | C. | 700° | C. | — | — | | |
| Ramp 1 | 700° | C. | 1000° | C. | 6 | 50 | 0.072 | 1 |
| Ramp 2 | 1000° | C. | 1100° | C. | 1.5 | 67 | 0.072 | 1 |
| Anneal | 1100° | C. | 1100° | C. | — | 10 | 0.072 | 1 |
| Ramp down 1 | 1100° | C. | 1000° | C. | 1.5 | 67 | 0.072 | 1 |
| Ramp down 2 | 1000° | C. | 700° | C. | 3 | 100 | 0.072 | 1 |
| Unload | 700° | C. | 700° | C. | — | — | | |

This example process forms silicon oxynitride layer (SiON) 224 on the surface of field-relief nitride 222′. Experimental evidence shows that the thickness of silicon oxynitride layer 224 should be at least about 2 nm thick to provide adequate protection of field-relief nitride 222′ from subsequent phosphoric acid etch steps and, in some implementations, it may be beneficial that the silicon oxynitride layer be at least about 3 nm thick. Of importance, oxidizing silicon nitride field layer 222 does not require an additional masking step to create a protective layer like silicon oxynitride layer 224, as compared to forming a patterned protective layer, such as a patterned silicon dioxide layer. Not only does this avoid the expense of another patterning step, but experimental results show that patterning the protective layer and subsequent etching can cause unevenness and other damage to silicon dioxide layer 208 in the gate area of LDMOS transistor 200. Such effects are avoided by the disclosed oxidation scheme.

FIG. 2F shows the transistor 200 in a later stage of formation, in which a silicon nitride layer 209 and photoresist layer 211 have been formed and patterned. Isolation trenches 215 have been formed at openings in the silicon nitride layer 209 for shallow trench isolation (STI) regions. In FIG. 2G, silicon dioxide liners 217 have been formed, e.g. by thermal oxidation, on the sidewalls of trenches 215 to a thickness of about 10 nm. The remainder of trenches 215 have been filled with polycrystalline silicon to form trench fill polysilicon 219 using, e.g., CVD. FIG. 2G shows that a top surface of the trench fill polysilicon 219 is about coplanar with a top surface of the of epitaxial layer 206, but in some physical implementations the top surface of the trench fill polysilicon 219 may extend above the top surface of the epitaxial layer 206. A CMP process may be used to remove any such polysilicon, as well as a majority of the silicon nitride layer 209. A remaining portion of silicon nitride layer 209 may be is removed using hot phosphoric acid. Of importance, silicon oxynitride layer 224 protects field-relief nitride 222′ from this hot phosphoric acid step. The exposed portions of silicon dioxide layer 208 may be damaged by this step, or presumed to be damaged, and may therefore be regrown thermally, optionally with a preceding HF oxide strip. The silicon oxynitride layer 224 prevents significant additional oxidation of the field-relief nitride 222′.

FIG. 2H illustrates the transistor 200 in a later stage of manufacturing. Implant 214 implants dopant ions into epitaxial layer 206 around the bottom of cavity 213 to form doped region 216. In various examples the implanted dopant is the second conductivity type, e.g. n-type. A resist layer, not shown, may be used to mask portions of the transistor 200 outside the cavity 213 from the implanted dopant. Doped region 216 may beneficially limit localized high electric fields in the extended drain of LDMOS transistor 200.

FIG. 2I shows the transistor 200 after formation of a gate electrode 228. Forming the gate electrode 228 may include depositing a layer of in-situ doped polycrystalline silicon using CVD and patterning the polycrystalline silicon layer. Gate electrode 228 extends over the field-relief nitride 222′, thus also serving as a field plate to control electric fields in the extended drain region of LDMOS transistor 200. In addition, because silicon nitride has a higher dielectric constant (about 7.5) than silicon dioxide (about 3.9) the field plate effect of gate electrode 228 is enhanced relative to a silicon dioxide dielectric, such as a LOCOS layer. FIG. 2J shows that source 230 and drain contact 232 are formed in epitaxial layer 206, which may be accomplished by masked implantation of dopant ions followed by annealing.

In FIG. 2K openings 240 have been formed in silicon dioxide layer 208 above source contact 230 and drain contact 232. This may be accomplished by masked etching of silicon dioxide layer 208. Silicided regions may be formed on the source and drain contact 230, 232 in a later stage of manufacturing, as further explained hereinbelow. In some examples a silicide blocking layer (SiBLK, not shown) including CVD silicon oxide and/or CVD silicon nitride is formed over the silicon dioxide layer 208 prior to forming the openings 240. Openings 240 as shown in FIG. 2K and an opening to gate electrode 228 are then etched in the silicon dioxide layer 208 and SiBLK layer, if present. In addition, sidewall spacers 229 are formed on sidewalls of gate electrode 228 by depositing a layer of silicon nitride by CVD and performing an anisotropic etch process. In addition, a silicon oxynitride layer 229′ may be optionally formed on sidewall spacers 229 using the same process described with respect to the silicon oxynitride layer 224. This optional silicon oxynitride layer may help protect sidewall spacers 229 in subsequent steps that may involve hot phosphoric acid cleanup. In some examples a layer or layers of the SiBLK may also provide a portion of the sidewall spacers. A layer of metal such as titanium, tantalum, cobalt, nickel, tungsten, and molybdenum is then deposited overall, e.g. by sputtering (physical vapor deposition, or PVD). An annealing step causes the metal to react with silicon to form drain silicide region 242, source silicide region 244 and gate silicide region 246 as shown in FIG. 2L. The unreacted metal may be removed by wet etching using an etchant appropriate for the metal used.

FIG. 2M shows the transistor 200 after forming pre-metal dielectric (PMD) layer 247 and first metal layer 256. PMD layer 247 may be formed overall by CVD of tetraethyl orthosilicate (TEOS) to a thickness of several hundred nanometers, for example. Unreferenced vias are formed in holes etched in PMD layer 247 to connect to drain silicide region 242, source silicide region 244 and gate silicide region 246. The via holes are filled with a conductive material such as copper, titanium, tungsten, or aluminum. A metal layer 256, such as copper or aluminum, is then deposited over the PMD layer 247 and patterned using photolithography to form lead 250, lead 252 and lead 254. The resulting LDMOS transistor 200 is analogous to LDMOS transistor 100 of FIG. 1.

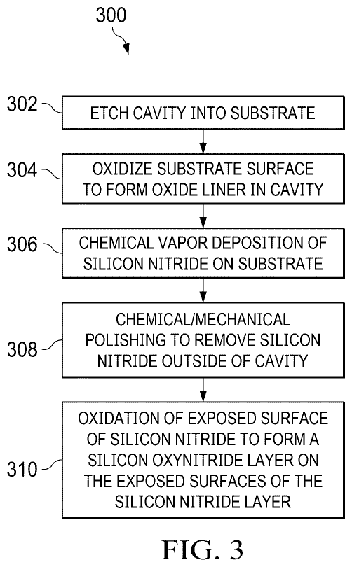

FIG. 3 is a flow diagram of a method 300 that may correspond to one or more of the process steps shown or described with respect to FIGS. 2A-2M, collectively FIG. 2. In particular, method 300 describes steps for forming a silicon nitride field relief layer 222′ (FIG. 2). Step 302 forms a cavity in a substrate. This cavity may correspond to cavity 213 of FIG. 2. As noted hereinabove, etching cavity 213 provides for some control over the contours of cavity 213. Step 304 oxidizes the substrate surface to form an oxide liner in the cavity. The oxide liner may correspond to silicon dioxide layer 208 of FIG. 2. In step 306 a silicon nitride layer is formed over the substrate, e.g. by CVD. The silicon nitride layer may correspond to silicon nitride field layer 222 as shown in FIG. 2D. In step 308 the silicon nitride layer is partially removed, e.g. by CMP, to remove the silicon nitride layer outside of the cavity. This step results in the configuration of silicon nitride field relief layer 222′ as shown in FIG. 2E. In step 310 the exposed surface of the silicon nitride field relief layer is oxidized to form a silicon oxynitride layer over the silicon nitride layer within the cavity. This step results in the silicon oxynitride layer 224 as shown in FIG. 2E.

Modifications are possible in the described examples, and other examples are possible, within the scope of the claims.

What is claimed is:

1. An integrated circuit comprising:
a trench extending into a semiconductor substrate;
a silicon nitride body within the trench;
a polysilicon electrode extending over the silicon nitride body; and
a silicon oxynitride layer between the silicon nitride body and the polysilicon electrode.

2. The integrated circuit of claim 1, further comprising a dielectric liner between the silicon nitride body and the semiconductor substrate.

3. The integrated circuit of claim 2, wherein the dielectric liner is a silicon dioxide layer.

4. The integrated circuit of claim 3, wherein the silicon dioxide layer touches the silicon oxynitride layer.

5. The integrated circuit of claim 1, further comprising a gate electrode that extends over the silicon nitride body and touches the silicon oxynitride layer.

6. The integrated circuit of claim 1, wherein the silicon oxynitride layer is at least 2 nm thick.

7. The integrated circuit of claim 1, wherein the silicon oxynitride layer extends from a drain region of a laterally diffused metal-oxide semiconductor (LDMOS) transistor to a channel region of the LDMOS transistor.

8. An electronic device, comprising:
an epitaxial layer over a semiconductor substrate;
a transistor in or over the epitaxial layer, including:
a source and a drain formed in the epitaxial layer;
a cavity in a surface of the epitaxial layer between the source and the drain;
a silicon nitride body in the cavity;
a gate electrode extending from the source toward the drain;
a gate dielectric between the gate electrode and the semiconductor substrate that extends from the source toward the drain;
a silicon oxynitride layer between the gate electrode and the silicon nitride body.

9. The integrated circuit of claim 8, further comprising a dielectric liner between the silicon nitride body and the semiconductor substrate.

10. The integrated circuit of claim 8, wherein the silicon oxynitride layer is at least 2 nm thick.

11. The integrated circuit of claim 8, further comprising a doped region in the semiconductor substrate extending from the cavity into the epitaxial layer.

12. The integrated circuit of claim 8, wherein the gate includes polycrystalline silicon.

13. A method of forming an integrated circuit, comprising:
forming a silicon nitride body over a semiconductor substrate; and
heating the silicon nitride body in the presence of oxygen, thereby forming a silicon oxynitride layer on the silicon nitride body and having a thickness of at least 2 nm.

14. The method of claim 13, further comprising forming a silicon dioxide layer on the semiconductor substrate, and forming the silicon nitride body on the silicon dioxide layer.

15. The method of claim 13, wherein the silicon nitride body is formed within a trench in the semiconductor substrate.

16. The method of claim 13, wherein the silicon nitride body is located between a source and a drain of a field-effect transistor.

17. The method of claim 13, wherein the silicon nitride body is heated to a temperature in a range from 900° C. to 1,100° C. for at least 20 minutes.

18. The method of claim 13, further comprising:
forming a trench in the semiconductor substrate;
forming a silicon dioxide layer on a surface of the semiconductor substrate and on a surface of the shallow trench;
forming a silicon nitride layer within the shallow trench and over the surface of the semiconductor substrate;
planarizing the silicon nitride layer thereby removing the silicon nitride layer from over the surface and forming the silicon nitride body; and
then performing the heating.

19. The method of claim 18, further comprising:
forming a source region and drain region in the semiconductor substrate, the silicon nitride body located between the source region and the drain region; and
forming a gate electrode on the silicon dioxide layer between the source region and the silicon nitride body and extending over the silicon nitride body.

20. The method of claim 13, further comprising oxidizing a silicon nitride sidewall spacer on a sidewall of the polysilicon electrode.
